(19) United States
(12) Patent Application Publication
(10) Pub. No.: US 2025/0329368 A1
(43) Pub. Date: Oct. 23, 2025

(54) MEMORY DEVICES, SYSTEMS AND REFRESH ADDRESS GENERATION CIRCUITS

(71) Applicant: YANGTZE MEMORY TECHNOLOGIES CO., LTD., Wuhan (CN)

(72) Inventors: Chengliang Hu, Wuhan (CN); Xiaodong Mei, Wuhan (CN); Huangpeng Zhang, Wuhan (CN)

(21) Appl. No.: 18/821,685

(22) Filed: Aug. 30, 2024

(30) Foreign Application Priority Data
Apr. 22, 2024 (CN) 202410488241.9

(51) Int. Cl. G11C 11/406; G11C 11/408

(52) U.S. Cl. CPC G11C 11/40618; G11C 11/40615; G11C 11/4085

(57) ABSTRACT

According to one aspect of the present disclosure, a memory device is provided. The memory device may include an array of memory cells including multiple word lines, and memory cells coupled to the word lines. The memory device may include a peripheral circuit coupled to the multiple word lines. The peripheral circuit may be configured to determine an aggressor row. The peripheral circuit may be configured to perform an uneven refresh for a victim row located on one side of the aggressor row.

### CROSS-REFERENCE TO RELATED APPLICATIONS

This application claims the benefit of priority to Chinese Application No. 202410488241.9, filed on Apr. 22, 2024, which is incorporated herein by reference in its entirety.

### FIELD OF TECHNOLOGY

The present application relates to the field of integrated circuits, and in example to memory devices, systems and refresh address generation circuits.

### BACKGROUND

With the gradual improvement of semiconductor manufacturing technology and the increasing integration of memory, the physical size of a memory cell is getting smaller and smaller, and the word lines in the memory cell are physically closer, thus, the capacitive coupling between adjacent word lines increases, and the data stored on the memory cell becomes more and more susceptible to be affected by the adjacent memory rows.

### SUMMARY

According to one aspect of the present disclosure, a memory device is provided. The memory device may include an array of memory cells including multiple word lines, and memory cells coupled to the word lines. The memory device may include a peripheral circuit coupled to the multiple word lines. The peripheral circuit may be configured to determine an aggressor row. The peripheral circuit may be configured to perform an uneven refresh for a victim row located on one side of the aggressor row.

In some implementations, the peripheral circuit may include a row hammer refresh control circuit configured to generate a row hammer refresh signal and an uneven refresh flag signal according to a refresh command signal and an adjustment signal. In some implementations, the peripheral circuit may include an aggressor row address determination circuit coupled to the row hammer refresh control circuit, and configured to, in response to the row hammer refresh signal, output an address of an aggressor row. In some implementations, the peripheral circuit may include a row hammer refresh address generation circuit coupled to the row hammer refresh control circuit and the aggressor row address determination circuit respectively, and configured to, in response to the row hammer refresh signal and the uneven refresh flag signal, generate an address for a row hammer refresh corresponding to the address of the aggressor row. In some implementations, if the uneven refresh flag signal indicates to perform the uneven refresh for the victim row located on the one side of the aggressor row, then the address for the row hammer refresh includes an address of the victim row located on the one side of the aggressor row.

In some implementations, the adjustment signal may represent a proportion of the uneven refresh in the row hammer refresh.

In some implementations, if the uneven refresh flag signal indicates to perform a refresh for victim rows on both sides of the aggressor row, then the address for the row hammer refresh may include addresses of victim rows located on the both sides of the address of the aggressor row.

In some implementations, the uneven refresh flag signal being at a high level may indicate to perform the uneven refresh for the victim row located on the one side of the aggressor row. In some implementations, the uneven refresh flag signal being at a low level may indicate to perform the refresh for the victim rows on the both sides of the aggressor row.

In some implementations, the row hammer refresh control circuit may be further configured to generate a row hammer refresh address generation signal according to the refresh command signal and the adjustment signal. In some implementations, the row hammer refresh address generation circuit may be further configured to, in response to the row hammer refresh address generation signal, the row hammer refresh signal, and the uneven refresh flag signal, generate the address for the row hammer refresh.

In some implementations, if the uneven refresh flag signal indicates to perform the uneven refresh for the victim row located on the one side of the aggressor row, then the row hammer refresh address generation signal may include a single pulse signal corresponding to the row hammer refresh signal. In some implementations, if the uneven refresh flag signal indicates to perform the refresh for victim rows on both sides of the aggressor row, then the row hammer refresh address generation signal may include a double pulse signal corresponding to the row hammer refresh signal.

In some implementations, the peripheral circuit may further include a normal refresh address generation circuit coupled to the row hammer refresh control circuit, and configured to receive the refresh command signal and the row hammer refresh signal, and output an address for a normal refresh according to the refresh command signal and the row hammer refresh signal.

In some implementations, the peripheral circuit may further include a first multiplexer coupled to the row hammer refresh control circuit, the row hammer refresh address generation circuit, and the normal refresh address generation circuit respectively. In some implementations, the first multiplexer may be configured to receive the address for the row hammer refresh, the address for the normal refresh, and the row hammer refresh signal. In some implementations, the first multiplexer may be configured to output the address for the row hammer refresh in response to the row hammer refresh signal being at a first level, or output the address for the normal refresh in response to the row hammer refresh signal being at a second level.

In some implementations, the row hammer refresh address generation circuit may include a first victim row address generation circuit coupled to the aggressor row address determination circuit and the row hammer refresh control circuit. In some implementations, first victim row address generation circuit may be configured to: receive the address of the aggressor row and the row hammer refresh signal, and generate the address of the victim row located on the one side of the address of the aggressor row. In some implementations, the row hammer refresh address generation circuit may include a second victim row address generation circuit coupled to the aggressor row address determination circuit and the row hammer refresh control circuit. In some implementations, the second victim row address generation circuit may be configured to: receive the address of the aggressor row and the row hammer refresh signal, and generate addresses of victim rows located on both sides of the address of the aggressor row.

In some implementations, the row hammer refresh address generation circuit may further include a second multiplexer coupled to the first victim row address generation circuit, the second victim row address generation circuit, and the row hammer refresh control circuit respectively. In some implementations, the second multiplexer may be configured to, in response to the uneven refresh flag signal indicating to perform the uneven refresh for the victim row located on the one side of the aggressor row, output the address of the victim row located on the one side of the address of the aggressor row. In some implementations, the second multiplexer may be configured to, in response to the uneven refresh flag signal indicating to perform a refresh for the victim rows on the both sides of the aggressor row, output the addresses of the victim rows located on the both sides of the address of the aggressor row.

In some implementations, the row hammer refresh control circuit may include a counter configured to record a number of pulses of the row hammer refresh signal and output the number of pulses as a count value. In some implementations, the row hammer refresh control circuit may include a comparator coupled to the counter. In some implementations, the comparator may be configured to compare the count value with the adjustment signal. In some implementations, the comparator may be configured to output the corresponding uneven refresh flag signal according to a result of comparing.

In some implementations, the comparator may be further configured to, when the count value matches the adjustment signal, output the uneven refresh flag signal indicating to perform the uneven refresh for the victim row located on the one side of the aggressor row. In some implementations, the comparator may be further configured to, when the count value does not match the adjustment signal, output the uneven refresh flag signal indicating to perform a refresh for the victim rows on both sides of the aggressor row.

In some implementations, distances from word lines located on both sides of the aggressor row to the aggressor row may not be equal. In some implementations, the peripheral circuit may be further configured to take a word line located on one side closer to the aggressor row as the victim row to perform the uneven refresh.

In some implementations, the memory device may include a Dynamic Random Access Memory.

According to another aspect of the present disclosure, a memory system is provided. The memory system may include one or more memory devices. The one or more memory devices may each include an array of memory cells including multiple word lines, and memory cells coupled to the word lines. The one or more memory devices may each include a peripheral circuit coupled to the multiple word lines. The peripheral circuit may be configured to determine an aggressor row. The peripheral circuit may be configured to perform an uneven refresh for a victim row located on one side of the aggressor row. The memory system may include a memory controller coupled to the memory devices and configured to control the memory device.

According to a further aspect of the present disclosure, a refresh address generation circuit may be provided. The refresh address generation circuit may include a row hammer refresh control circuit configured to generate a row hammer refresh signal and an uneven refresh flag signal according to a refresh command signal and an adjustment signal. The refresh address generation circuit may include an aggressor row address determination circuit coupled to the row hammer refresh control circuit, and configured to, in response to the row hammer refresh signal, output an address of an aggressor row. The refresh address generation circuit may include a row hammer refresh address generation circuit coupled to the row hammer refresh control circuit and the aggressor row address determination circuit respectively, and configured to, in response to the row hammer refresh signal and the uneven refresh flag signal, generate an address for a row hammer refresh corresponding to the address of the aggressor row. If the uneven refresh flag signal indicates to perform an uneven refresh for a victim row located on one side of the aggressor row, then the address for the row hammer refresh may include the address of the victim row located on the one side of the aggressor row.

In some implementations, the refresh address generation circuit may include a normal refresh address generation circuit coupled to the row hammer refresh control circuit. In some implementations, the normal refresh address generation circuit may be configured to receive the refresh command signal and the row hammer refresh signal. In some implementations, the normal refresh address generation circuit may be configured to output an address for a normal refresh according to the refresh command signal and the row hammer refresh signal.

In some implementations, the refresh address generation circuit may include a first multiplexer coupled to the row hammer refresh control circuit, the row hammer refresh address generation circuit and the normal refresh address generation circuit respectively. In some implementations, the first multiplexer may be configured to receive the address for the row hammer refresh, the address for the normal refresh and the row hammer refresh signal. In some implementations, the first multiplexer may be configured to output the address for the row hammer refresh in response to the row hammer refresh signal being at a first level, or output the address for the normal refresh in response to the row hammer refresh signal being at a second level.

According to still another aspect of the present disclosure, a method of hammer refreshing is provided. The method may include, in response to a row hammer refresh signal, receiving an address of an aggressor row. The method may include, in response to an uneven refresh flag signal, generating an address for a row hammer refresh corresponding to the address of the aggressor row. If the uneven refresh flag signal indicates to perform an uneven refresh for a victim row located on one side of the aggressor row, the address for the row hammer refresh may include an address of the victim row located on the one side of the aggressor row. The method may include performing a row hammer refresh based on the address for the row hammer refresh.

In some implementations, if the uneven refresh flag signal indicates to perform a refresh for victim rows on both sides of the aggressor row, the address for the row hammer refresh may include addresses of the victim rows located on the both sides of the address of the aggressor row.

### BRIEF DESCRIPTION OF THE DRAWINGS

In the accompanying drawings, unless otherwise specified, same reference numbers refer to same or similar parts or elements throughout multiple accompanying drawings. The accompanying drawings are not necessarily to scale. It should be understood that these accompanying drawings depict only some examples in accordance with the present application and should not be considered as limiting the scope of the present application.

FIG. 1 is a schematic block diagram of an illustrated electronic device, according to an example of the present application.

FIG. 2A is a schematic block diagram of an illustrated Solid-State Drive (SSD) or Universal Flash Storage (UFS), according to an example of the present application.

FIG. 2B is a schematic block diagram of an illustrated memory, according to an example of the present application.

FIG. 3 is a schematic structural diagram of an illustrated dynamic random-access memory, according to an example of the present application.

FIG. 4 is a schematic diagram of the connection relationship among word lines, bit lines and memory cells of an illustrated dynamic random-access memory, according to an example of the present application.

FIG. 5 is a distribution schematic diagram of an array of memory cells and peripheral circuit in an illustrated memory device, according to an example of the present application.

FIG. 6 is a schematic block diagram of an illustrated word line distribution, according to an example of the present application.

FIG. 7 is a structure schematic diagram 1 of illustrated peripheral circuit, according to an example of the present application.

FIG. 8 is a structure schematic diagram 2 of illustrated peripheral circuit, according to an example of the present application.

FIG. 9 is a structure schematic diagram 3 of illustrated peripheral circuit, according to an example of the present application.

FIG. 10 is a schematic block diagram 1 of an illustrated signal waveform, according to an example of the present application.

FIG. 11 is a schematic block diagram 2 of an illustrated signal waveform, according to an example of the present application.

FIG. 12 is a structure schematic diagram 1 of an illustrated row hammer refresh address generation circuit, according to an example of the present application.

FIG. 13 is a structure schematic diagram 2 of an illustrated row hammer refresh address generation circuit, according to an example of the present application.

FIG. 14 is a structure schematic diagram of an illustrated row hammer refresh control circuit, according to an example of the present application.

FIG. 15 is a schematic flowchart of the implementation of an illustrated row hammer refreshing method, according to an example of the present application.

### DETAILED DESCRIPTION

Illustrated implementations applied in the present application will be described in more detail below with reference to the accompanying drawings. Although illustrated implementations of the present application are shown in the accompanying drawings, it should be understood that the present application may be implemented in various forms and should not be limited to the specific implementations set forth herein. Rather, these examples are provided so that the present application can be more thoroughly understood and the scope of the present application can be fully conveyed to those skilled in the art.

In the following description, numerous specific details are given in order to provide a more thorough understanding of the present application. However, it will be apparent to one skilled in the art that the present application may be practiced without one or more of these details. In other examples, in order to avoid confusion with the present application, some technical features known in the art are not described; that is, not all features of the actual example are described here, and well-known functions and structures are not described in detail.

In the accompanying drawings, size of a layer, a region, an element and their relative sizes may be exaggerated for clarity. Like reference numerals refer to like elements throughout.

It will be understood that when an element or layer is referred to as being “on,” “adjacent to,” “connected to” or “coupled to” another element or layer, it may be directly on, adjacent to, connected to or coupled to another element or layer, or intervening elements or layers may be present. In contrast, when an element is referred to as being “directly on,” “directly adjacent to,” “directly connected to” or “directly coupled to” another element or layer, there is no intervening elements or layers present. It will be understood that, although the terms first, second, third etc., may be used to describe various elements, components, regions, layers and/or parts, these elements, components, regions, layers and/or parts should not be limited by these terms. These terms are only used to distinguish one element, component, region, layer or part from another element, component, region, layer or part. Thus, a first element, component, region, layer or part discussed below may be termed as a second element, component, region, layer or part without departing from teachings of the present application. Whereas a second element, component, region, layer or part is discussed, it does not indicate that a first element, component, region, layer or part necessarily presents in the present application.

The spatially relative terms such as “beneath”, “below”, “lower”, “under”, “above”, “on”, etc., may be used herein for ease of description to describe one element or feature's relationship to another element(s) or feature(s) as illustrated in the figures. It will be understood that the spatially relative terms are intended to encompass different orientations of the device in use or operations in addition to the orientation depicted in the figures. For example, if the device in the appended drawings is turned over, an element or a feature described as “below” or “beneath” or “under” another element or feature would then be oriented “above” the another element or feature. Thus, illustrated terms “below” and “under” may encompass both directions of up and down. A device may be otherwise oriented (rotated 90 degrees or at other orientations) and the spatially relative descriptors used herein should be interpreted accordingly.

A term used herein is for the purpose of describing a particular example only and is not to be considered as limitation of the present application. As used herein, the singular forms “a”, “an” and “said/the” are intended to include the plural forms as well, unless the context clearly dictates otherwise. It should also be understood that the terms “consists of” and/or “comprising”, when used in this description, identify the presence of stated features, integers, operations, operations, elements and/or parts, but do not exclude the presence or addition of one or more other features, integers, operations, operations, elements, parts and/or groups. As used herein, the term “and/or” includes any and all combinations of the associated listed items. For transmission lines, the units “a”, “an” or “a piece” all represent the same meaning.

In order to understand the characteristics and technical content of examples of the present application in more detail, implementations of examples of the present application will be described in detail below in conjunction with the accompanying drawings, however, the accompanying drawings are for reference and description only, and are not intended to limit examples of the present application.

As the operating frequency of the memory increases, the word line will be activated more frequently or activated for a long time, which will cause the row hammer problem of the memory to become more and more serious. How to effectively solve the row hammer problem is an urgent problem that needs to be solved.

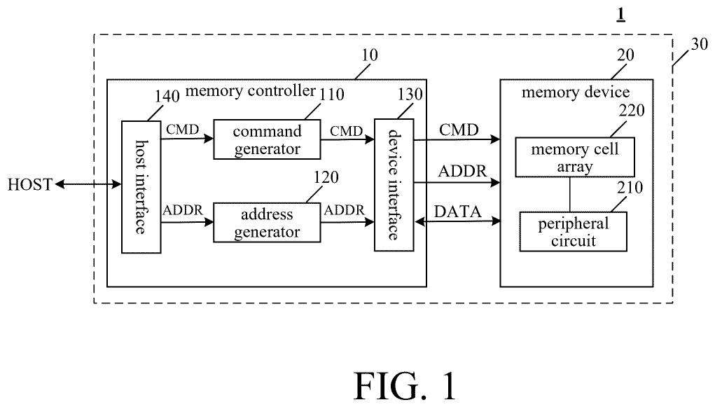

FIG. 1 shows a schematic block diagram of an illustrated electronic device, according to an example of the present application. The electronic device 1 may be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having memory device therein. As shown in FIG. 1, the electronic device 1 may include a host HOST and a memory system 30, and the memory system 30 includes a memory controller 10 and one or more memory devices 20. The host HOST may be a processor of the electronic device (e.g., a Central Processing Unit (CPU) or a Graphic Processing Unit (GPU)). The host HOST may be configured to send data to or receive data from memory device 20. The memory controller 10 is coupled to the memory device 20 and the host HOST and is configured to control the memory device 20. The memory controller 10 may manage data stored in the memory device 20 and communicate with the host HOST.

The memory controller 10 may be configured to control operations of memory device 20, e.g., read, erase, write, and refresh operations. In some implementations, memory controller 10 is further configured to process Error Correction Code (ECC) related to data read from or written to memory device 20. The memory controller 10 may also perform any other suitable functions, e.g., formatting the memory device 20.

In some specific examples, the memory controller 10 and one or more memory devices 20 may be integrated into various types of electronic devices, e.g., the memory controller 10 may be integrated into the north bridge of the computer motherboard or directly integrated into the computer CPU, and multiple memory devices 20 may be integrated into a memory stick. That is, memory system 30 may be implemented and packaged into different types of end electronic products.

The memory controller 10 may send/receive data to/from the host HOST, and may send a command CMD and an address ADDR to the memory device 20. The memory controller 10 may include a command generator 110, an address generator 120, a device interface 130, and a host interface 140. The host interface 140 may receive the command CMD and the address ADDR from the host HOST, and the command generator 110 may generate an access command, a row hammer refresh command, etc., through decoding the command CMD received from the host HOST, and may provide the access command and row hammer refresh command to the memory device 20 through the device interface 130. The access command may be a signal that instructs the memory device 20 to write or read data through accessing the row of the array of memory cells 220 corresponding to the address ADDR. The row hammer refresh command may be a signal that commands memory device 20 to perform additional refresh operation on a word line adjacent to the word line that is intensively accessed in a short period of time. In other words, an additional refresh operation may be performed on a word line adjacent to the word line that is accessed multiple times in a short period of time.

The address generator 120 in the memory controller 10 may generate row addresses and column addresses to be accessed in the array of memory cells 220 by decoding the address ADDR received from the host interface 140. Additionally, the memory device 20 may generate an address of a bank to be accessed when the array of memory cells 220 includes multiple banks.

Additionally, the memory controller 10 may control memory operations such as write and read by providing various signals to the memory device 20 via device interface 130. For example, the memory controller 10 may provide a write command to the memory device 20. The write command may be used to instruct the memory device 20 to perform a write operation to store data into the memory device 20.

In some examples, the memory device 20 includes an array of memory cells 220 and a peripheral circuit 210, where the array of memory cells 220 includes multiple banks, each bank includes multiple blocks, and each memory block includes multiple memory cell rows and multiple memory cell columns, each memory cell row is coupled to a corresponding word line, and each memory cell column is coupled to a corresponding bit line. The peripheral circuit 210 may write data DATA into the array of memory cells or read data DATA from the array of memory cells 220 and send the data DATA to the memory controller 10 based on the command CMD and the address ADDR received from the memory controller 10, or may provide a control signal CTRL for refreshing the memory cells included in the array of memory cells 220 to the row decoding circuit and the column decoding circuit. In other words, the peripheral circuit 210 may perform all operations to process data in the array of memory cells 220. The peripheral circuit 210 may include: a control circuit corresponding to each memory block, e.g., a Sensing Amplifier (SA) and a Word-Line Driver (WLD), etc., a control circuit corresponding to each memory bank, e.g., a row decoding circuit, a column decoding circuit, etc., and a control circuit corresponding to all memory banks, e.g., a command buffer, a command decoder, an address buffer, a data input/output buffer, a mode register, etc.

The memory device 20 may be Random Access Memory (RAM), such as Dynamic Random Access Memory (DRAM), synchronous DRAM (SDRAM), static RAM (SRAM), Double Data Rate SDRAM (DDR SDRAM), DDR2 SDRAM, DDR3 SDRAM, Phase Change RAM (PRAM), Magnetic RAM (MRAM), Resistive RAM (RRAM), etc. The following description only takes DRAM as an example for explanation.

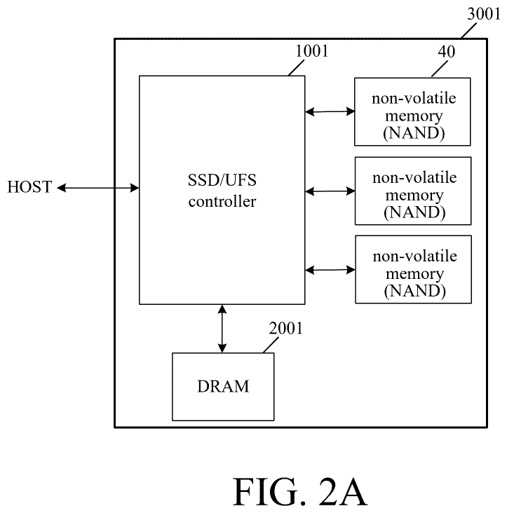

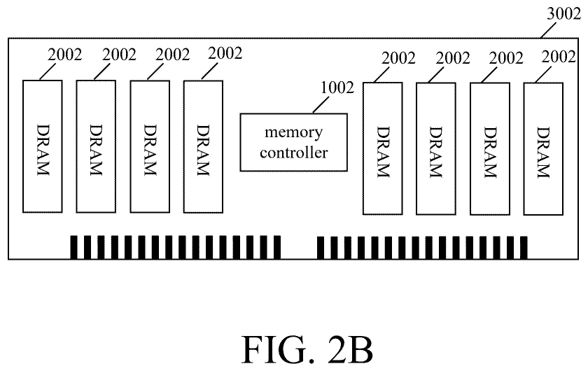

FIG. 2A is a schematic block diagram of an illustrated SSD/UFS, according to an example of the present application. Here, SSD/UFS may be understood as a type of memory system in FIG. 1, in this example, DRAM may be used as a buffer memory.

As shown in FIG. 2A, the SSD/UFS 3001 may include an SSD/UFS controller 1001, a DRAM 2001 and a non-volatile memory 40. The SSD/UFS controller 1001 may provide a physical connection between the host HOST and the SSD/UFS 3001. That is, the SSD/UFS controller 1001 may provide an interface between the host HOST and the SSD/UFS 3001 according to the bus format of the host. The SSD/UFS controller 1001 may decode instructions provided from the host HOST. The SSD/UFS controller 1001 may access the non-volatile memory 40 based on the decode result. The DRAM 2001 may temporarily store written data provided from the host HOST, or data read from the non-volatile memory 40. When the host HOST issues a read request, if the data existing in the non-volatile memory 40 is cached, the DRAM 2001 may support a cache function for directly providing the cached data to the host HOST. The data transfer rate through the bus format (e.g., SATA or SAS) of the host is much higher than the data transfer rate of the memory channel of the SSD/UFS 3001. That is, when the interface speed of the host is significantly high, performance degradation due to the speed difference may be minimized by providing high-capacity DRAM 2001. In addition, the DRAM 2001 may store the address mapping table of the non-volatile memory 40. DRAM 2001 may include, but is not limited to, DRAM. The non-volatile memory 40 may be configured as a storage medium of the SSD/UFS 3001. Non-volatile memory 40 may include, but is not limited to, NAND type memory.

FIG. 2B is a schematic block diagram of an illustrated memory, according to an example of the present application; here, memory may be understood as a type of memory system in FIG. 1, in this example, DRAM may be used as a storage medium.

As shown in FIG. 2B, the memory 3002 may be easily attached or installed to or detached from the electronic device 1 through the illustrated interface. The memory 3002 may include multiple volatile memories 2002 (e.g., DRAM) and a memory controller 1002. The memory 3002 may be used to write data, store data, retrieve (or, read) data, and/or erase data under the control of the processor of the computer. In some examples, the controller memory controller 1002 may communicate with the DRAM using at least one communication protocol or technology standard commonly associated with, e.g., dual in-line memory modules (DIMMs), Registered DIMM (RDIMM), low load DIMM (LRDIMM), un-registered DIMM (UDIMM), etc.

In some examples, the DRAM 2001 in FIG. 2A and the volatile memory 2002 in FIG. 2B are both application scenarios of the memory device 20 in FIG. 1, and may also be applied to other application scenarios, which are not limited here.

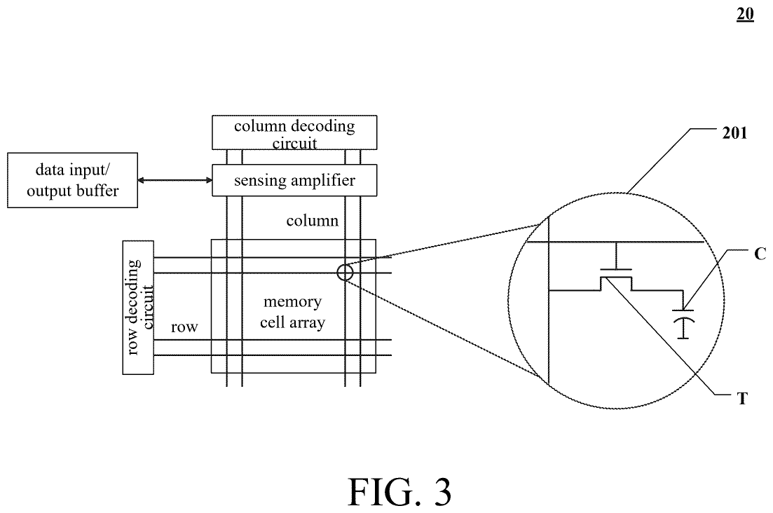

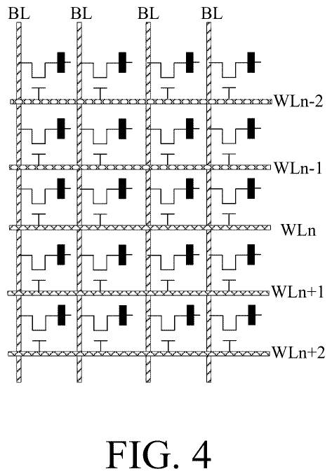

FIG. 3 is a schematic structural diagram of an illustrated dynamic random-access memory, according to an example of the present application. FIG. 4 is a schematic diagram of the connection relationship between word lines, bit lines and memory cells of an illustrated dynamic random-access memory, according to an example of the present application.

The right side of FIG. 3 shows the circuit of the memory cell in DRAM. DRAM includes at least one DRAM die. Each DRAM die includes an array of memory cells. The array of memory cells includes multiple memory cells 201 arranged in an array. Each memory cell 201 includes a transistor T and a capacitor C. The main working principle of the memory cell is to represent whether a binary bit is 1 or 0 with the amount of charge stored in the capacitor. The memory cells are arranged in an array, which may be regarded as a typical mesh structure, and reference may be made to FIG. 4 for details of the mesh structure. The array of memory cells employs a row and a column to specify an address. By specifying an intersection of a row and a column (by specifying a row address and a column address of a DRAM), a memory controller may independently access each memory cell in the DRAM die and perform operations such as read, write, or refresh for the data stored in it.

The left side of FIG. 3 shows the array of memory cells and some peripheral circuit in DRAM. In some examples, in response to the address input to the row decoding circuit, the row decoding circuit selects the word line to select the row of memory cells to be accessed. The row decoding circuit decodes the input address and enables (activates) the word line corresponding to the decoded address. The column decoding circuit selects one or more bit lines to input user output data into the portion of the row of memory cells that corresponds to the selected word line.

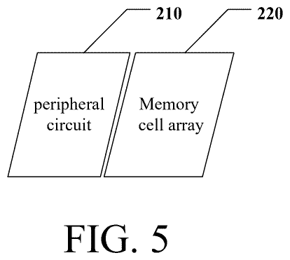

FIG. 5 is a distribution diagram of an array of memory cells and peripheral circuit in an illustrated memory device, according to an example of the present application. As shown in FIG. 5, the memory device includes an array of memory cells 220 and a peripheral circuit 210, where the array of memory cells 220 and the peripheral circuit 210 are coupled.

In some examples of the present application, the array of memory cells 220 and the peripheral circuit 210 are bonded in a manner including, but not limited to, hybrid bonding, anodic bonding, melt bonding, transfer bonding, adhesive bonding, eutectic bonding, etc.

Referring to FIG. 4 and FIG. 5, the array of memory cells 220 includes multiple word lines WLs (e.g., WLn−2˜WLn+1 shown in FIG. 4) and memory cells coupled to the word lines. If a certain word line is frequently activated (e.g., intensively accessed), then this word line may become an Aggressor Row, while adjacent word lines may become Victim Rows. For example, if word line WLn becomes an aggressor row, word lines WLn−2, WLn−1, WLn+1, and WLn+2 adjacent to word line WLn may all become victim rows.

In some examples, under the action of electromagnetic interference, the aggressor row is frequently activated, which may cause the charge of the memory cells coupled to the victim rows to leak, thereby causing bit-flipping of the data stored in the memory cells, so that 0 becomes 1, or 1 becomes 0. Therefore, an additional refresh operation, that is, a row hammer refresh, may be performed on the victim rows to replenish the charge of the memory cells coupled to the victim rows to avoid bit-flipping of the data.

In an example of the present application, the peripheral circuit 210 may determine at least one word line that has been activated more times in the multiple word lines WLs as the aggressor row, e.g., determine the top 5 of the word lines in ascending order of activated times as the aggressor rows. Furthermore, the peripheral circuit 210 may send a refresh command to a victim row adjacent to each aggressor row to perform a row hammer refresh.

In the example of the present application, a row hammer refresh may include an even refresh and an uneven refresh, where the even refresh is a refresh for victim rows located on both sides of the aggressor row, while the uneven refresh is a refresh for victim row(s) located on one side of the aggressor row. For example, if the word line WLn becomes the aggressor row, then a refresh is performed on both the word lines WLn−1 and WLn+1, or a refresh is performed on the word lines WLn−1 and WLn+1, and the word lines WLn−2 and WLn+2, which is the even refresh; and accordingly, a refresh is performed on the word line WLn−1 only, or a refresh is performed on the word line WLn+1 only, which is the uneven refresh.

It may be understood that compared with performing the even refresh for the victim rows located on both sides of the aggressor row, only performing an uneven refresh for the victim row located on one side of the aggressor row may save power consumption.

In some examples of the present application, the distances from the aggressor row to the word lines located on both sides of the aggressor row are not equal; the peripheral circuit 210 is further configured to take the word line on the side closer to the aggressor row as the victim row to perform an uneven refresh.

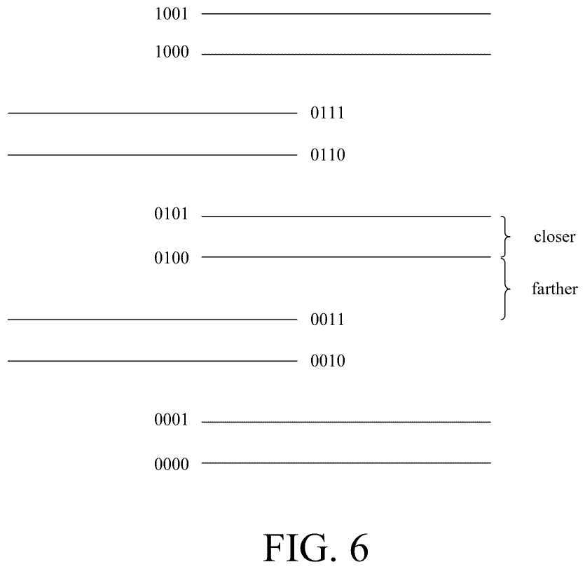

FIG. 6 shows multiple word lines, and the row addresses of the multiple word lines are 0000˜1001 in sequence. The distance between two adjacent word lines is uneven, and the two word lines whose last bits of the row address are inverted are relatively close to each other. For example, the distance between the word line 0100 and the word line 0101 is relatively close, while the distance between the word line 0100 and the word line 0011 is relatively far, that is to say, the distances from the word line 0100 to the word lines 0101 and 0011 located on both sides of the word line 0100 are not equal.

In the example of the present application, taking FIG. 6 as an example, if the word line 0100 is determined to be the aggressor row, then the peripheral circuit 210 takes only the word line 0101 close to the word line 0100 as the victim row, sends a refresh command for the word line 0101, and performs an uneven refresh.

It may be understood that the degree of affecting a certain word line (e.g., the row hammer threshold) by the row hammer is related to the distance between the word line and the aggressor row; that is, the closer the distance from the word line to the aggressor row is, the more susceptible it is to the row hammer. Therefore, by taking the word line on the side closer to the aggressor row as the victim row and performing an uneven refresh, the row hammer refresh may be performed in a more targeted manner, thus ensuring the effect of row hammer refresh and saving power consumption.

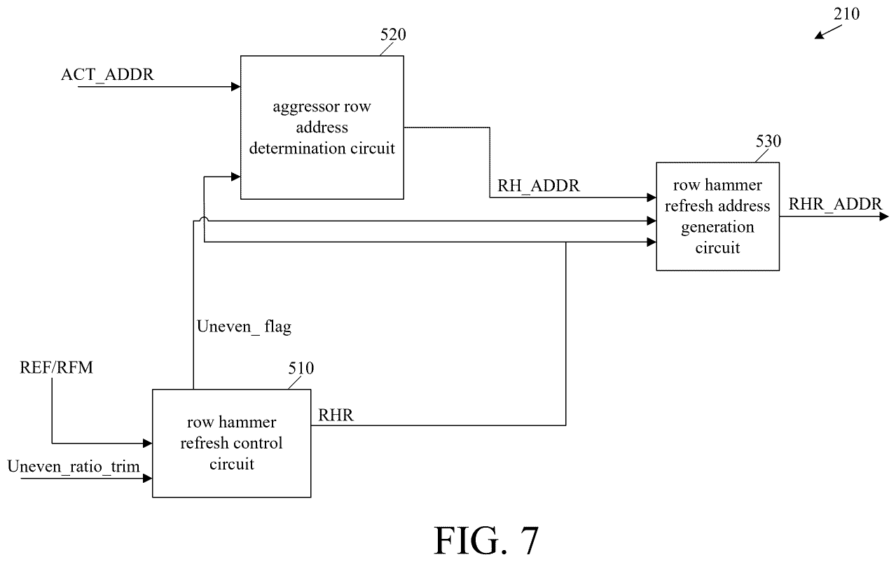

As shown in FIG. 7, in some examples of the present application, the peripheral circuit 210 includes: a row hammer refresh control circuit 510, an aggressor row address determination circuit 520, and a row hammer refresh address generation circuit 530.

Referring to FIG. 7, in some examples of the present application, the row hammer refresh control circuit 510 is configured to generate a row hammer refresh signal RHR and an uneven refresh flag signal Uneven_flag according to a refresh command signal CMD (e.g., REF/RFM) and an adjustment signal Uneven_ratio_trim.

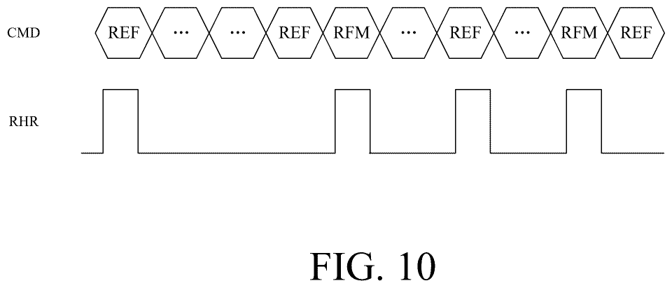

Referring to FIG. 10, the refresh command signal CMD is sent by the memory controller, and each pulse REF/RFM is sent according to a certain period. The row hammer refresh control circuit 510 may generate a pulse in the row hammer refresh signal RHR when triggered by part of the pulses in the refresh command signal CMD. That is to say, part of the pulses in the refresh command signal CMD will be used to perform a row hammer refresh.

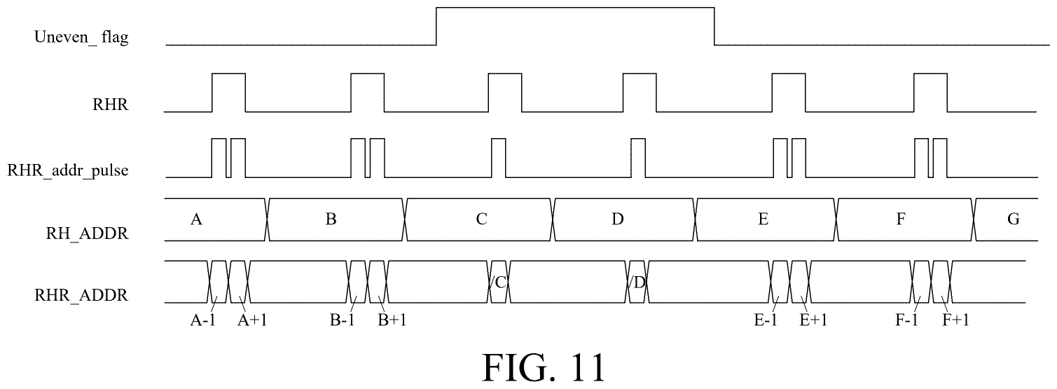

Referring to FIG. 11, the row hammer refresh control circuit 510 may also generate the uneven refresh flag signal Uneven_flag according to the adjustment signal Uneven_ratio_trim, where the uneven refresh flag signal Uneven_flag being at the first level (the example in FIG. 11 is high level) represents performing an uneven refresh. The time duration of the first level of the uneven refresh flag signal Uneven_flag is determined by the adjustment signal Uneven_ratio_trim.

In the example of the present application, the adjustment signal Uneven_ratio_trim represents the proportion of uneven refresh in the row hammer refresh. That is to say, the adjustment signal Uneven_ratio_trim indicates that the higher the proportion of uneven refresh in row hammer refresh is, the longer the first level of the uneven refresh flag signal Uneven_flag lasts.

Referring to FIG. 7, in the example of the present application, the aggressor row address determination circuit 520 is coupled to the row hammer refresh control circuit 510. The aggressor row address determination circuit 520 is configured to determine the aggressor row among the activated word lines, and to receive and respond to the row hammer refresh signal RHR to output the address of the aggressor row RH_ADDR.

Still referring to FIG. 7, the aggressor row address determination circuit 520 may receive the row addresses ACT_ADDR of the activated word lines, determine at least one word line that has been activated more times as the aggressor row, and output the address of the aggressor row RH_ADDR. In conjunction with FIG. 11, since each pulse in the row hammer refresh signal RHR triggers a row hammer refresh, therefore, the aggressor row address determination circuit 520 outputs an address of one aggressor row RH_ADDR every time it receives a pulse in the row hammer refresh signal RHR to perform a row hammer refresh.

Referring to FIG. 7, in an example of the present application, the row hammer refresh address generation circuit 530 is coupled to the row hammer refresh control circuit 510 and the aggressor row address determination circuit 520 respectively. The row hammer refresh address generation circuit 530 is configured to receive the address of the aggressor row RH_ADDR, the row hammer refresh signal RHR, and the uneven refresh flag signal Uneven_flag. The row hammer refresh address generation circuit 530 is configured to, in response to the row hammer refresh signal RHR and the uneven refresh flag signal Uneven_flag, generate an address for a row hammer refresh RHR_ADDR corresponding to the address of the aggressor row RH_ADDR. If the uneven refresh flag signal Uneven_flag indicates to perform the uneven refresh for the victim row located on one side of the aggressor row, the row hammer refresh address generation circuit 530 outputs the address of the victim row located one side of the aggressor row as the address for the row hammer refresh RHR_ADDR.

In some examples of the present application, the uneven refresh flag signal Uneven_flag being at a high level indicates to perform the uneven refresh for the victim row located on one side of the aggressor row.

Referring to FIG. 11, e.g., when the address of the aggressor row RH_ADDR received by the row hammer refresh address generation circuit 530 is C, the uneven refresh flag signal Uneven_flag is at the first level (the example in FIG. 11 is high level), the uneven refresh flag signal Uneven_flag indicates to perform uneven refresh for the victim row located on one side of the aggressor row C. Then, the output address for the row hammer refresh RHR_ADDR is/C, where the victim row/C is located on one side of the aggressor row C. When the address of the aggressor row RH_ADDR is D, the uneven refresh flag signal Uneven_flag is also at the first level, which may be understood by reference.

Referring again to FIG. 7, in some examples of the present application, if the uneven refresh flag signal Uneven_flag indicates to perform a refresh for the victim rows located on both sides of the aggressor row, the row hammer refresh address generation circuit 530 outputs the addresses of the victim rows located on both sides of the aggressor row as the addresses for the row hammer refresh RHR_ADDR to perform an even refresh.

In some examples of the present application, the uneven refresh flag signal Uneven_flag being at a low level indicates to perform a refresh for the victim rows located on both sides of the aggressor row.

Referring to FIG. 11, e.g., when the address of the aggressor row RH_ADDR received by the row hammer refresh address generation circuit 530 is A, the uneven refresh flag signal Uneven_flag is at the second level (the example in FIG. 11 is low level), the uneven refresh flag signal Uneven_flag indicates to perform a refresh for the victim rows located on both sides of the aggressor row A. Then, the outputted addresses for the row hammer refresh RHR_ADDR include A−1 and A+1, where the victim rows A−1 and A+1 are located on both sides of the aggressor row A respectively. When the address of the aggressor row RH_ADDR is B, E or F, the uneven refresh flag signal Uneven_flag is also at the second level, which may be understood by reference.

It may be understood that a certain proportion of row hammer refreshes is taken as uneven refreshes, and the row hammer refresh address generation circuit 530 only outputs the address of the victim row located on one side of the aggressor row as the address for the row hammer refresh RHR_ADDR, thus, the effect of row hammer refresh is ensured and power consumption is saved.

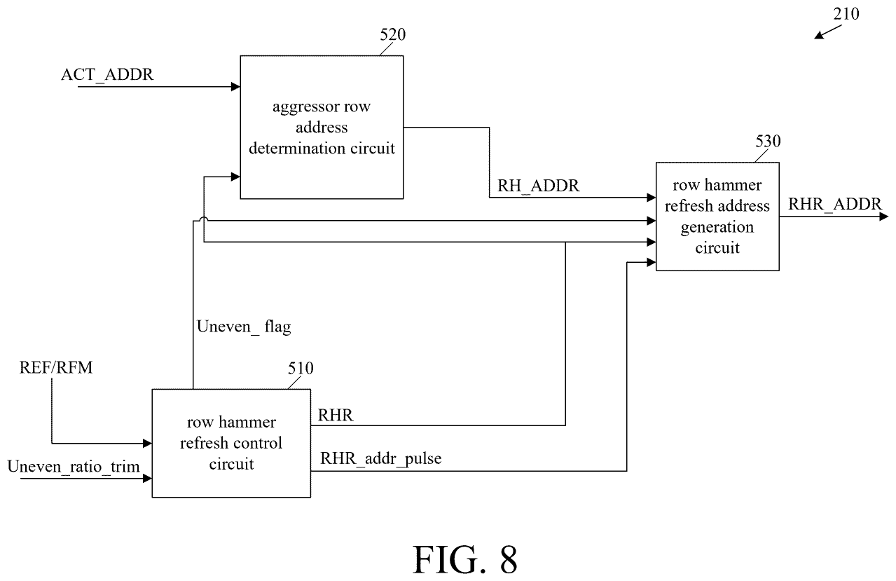

In some examples of the present application, as shown in FIG. 8, the row hammer refresh control circuit 510 is further configured to generate a row hammer refresh address generation signal RHR_addr_pulse according to the refresh command signal CMD (e.g., REF/RFM) and the adjustment signal Uneven_ratio_trim. The row hammer refresh address generation circuit 530 is further configured to generate the address for the row hammer refresh RHR_ADDR in response to the row hammer refresh address generation signal RHR_addr_pulse, the row hammer refresh signal RHR and the uneven refresh flag signal Uneven_flag.

Referring to FIG. 11, in some examples of the present application, the row hammer refresh control circuit 510 generates the row hammer refresh signal RHR according to the refresh command signal CMD, and may also generate the row hammer refresh address generation signal RHR_addr_pulse according to the uneven refresh flag signal Uneven_flag and in case of being triggered by the row hammer refresh signal RHR after generating the uneven refresh flag signal Uneven_flag according to the adjustment signal Uneven_ratio_trim.

In an example of the present application, the uneven refresh flag signal Uneven_flag indicates to perform the uneven refresh for the victim row located on one side of the aggressor row. The row hammer refresh address generation signal RHR_addr_pulse includes a single pulse signal corresponding to the row hammer refresh signal. Referring to FIG. 11, when the uneven refresh flag signal Uneven_flag is at the first level (the example in FIG. 11 is high level), the uneven refresh flag signal Uneven_flag indicates to perform an uneven refresh for the victim row located on one side of the aggressor row. Accordingly, each pulse in the row hammer refresh signal RHR triggers the generation of a corresponding pulse in the row hammer refresh address generation signal RHR_addr_pulse.

In an example of the present application, the uneven refresh flag signal Uneven_flag indicates to perform a refresh for the victim rows on both sides of the aggressor row, the row hammer refresh address generation signal RHR_addr_pulse includes a double pulse signal corresponding to the row hammer refresh signal. Referring to FIG. 11, when the uneven refresh flag signal Uneven_flag is at the second level (the example in FIG. 11 is low level), the uneven refresh flag signal Uneven_flag indicates to perform a refresh for the victim rows located on both sides of the aggressor row; accordingly, each pulse in the row hammer refresh signal RHR triggers the generation of corresponding two consecutive pulses in the row hammer refresh address generation signal RHR_addr_pulse.

Referring to FIG. 11, in an example of the present application, the row hammer refresh signal RHR and the row hammer refresh address generation signal RHR_addr_pulse may jointly control the generation of the address for the row hammer refresh RHR_ADDR and complement each other. In an aspect, when the row hammer refresh signal RHR is within the pulse range (e.g., high level), the address for the row hammer refresh RHR_ADDR may be generated; while when the row hammer refresh signal RHR is out of the pulse range (e.g., low level), no valid address for the row hammer refresh RHR_ADDR is generated. In another aspect, when the row hammer refresh address generation signal RHR_addr_pulse is a single pulse signal, the address of the victim row located on one side of the aggressor row is output as the address for the row hammer refresh RHR_ADDR; while when the row hammer refresh address generation signal RHR_addr_pulse is a double pulse signal, the addresses of the victim rows located on both sides of the aggressor row are output as the addresses for the row hammer refresh RHR_ADDR.

It may be understood that the row hammer refresh signal RHR and the row hammer refresh address generation signal RHR_addr_pulse are jointly used as the control signal of the row hammer refresh address generation circuit 530, thus, the generation of the address for the row hammer refresh RHR_ADDR may be more accurately controlled to avoid errors.

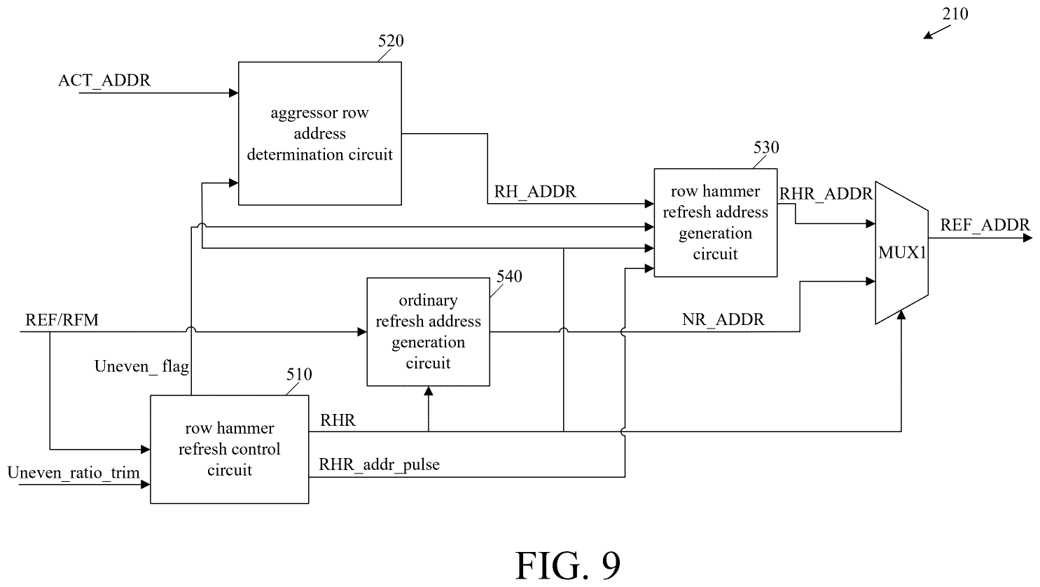

In some examples of the present application, referring to FIG. 9, the peripheral circuit 210 further includes: a normal refresh address generation circuit 540. The normal refresh address generation circuit 540 is coupled to the row hammer refresh control circuit 510. The normal refresh address generation circuit 540 is configured to receive the refresh command signal CMD (e.g., REF/RFM) and the row hammer refresh signal RHR, and output the address for the normal refresh NR_ADDR according to the refresh command signal CMD and the row hammer refresh signal RHR.

In the example of the present application, referring to FIG. 10, being out of the pulse range of the row hammer refresh signal RHR, that is, when the row hammer refresh signal RHR is at a low level, the normal refresh address generation circuit 540 may update the address for the normal refresh NR_ADDR for performing a normal refresh. The normal refresh is a normal refresh performed periodically by the memory. The address for the normal refresh NR_ADDR is generated with the internal count of the memory, and the address for the normal refresh NR_ADDR is updated during each REF period. Accordingly, being within the pulse range of the row hammer refresh signal RHR, that is, when the row hammer refresh signal RHR is at a high level, the row hammer refresh signal RHR may cover the refresh command signal CMD to avoid updating the address for the normal refresh NR_ADDR.

That is to say, being out of the pulse range of the row hammer refresh signal RHR, that is, when the row hammer refresh signal RHR is at a low level, the refresh command signal CMD is used to perform a normal refresh; while being within the pulse range of the row hammer refresh signal RHR. That is, when the row hammer refresh signal RHR is at a high level, the refresh command signal CMD is used to perform the row hammer refresh.

In some examples of the present application, referring to FIG. 9, the peripheral circuit 210 further includes: a first multiplexer MUX1. The first multiplexer MUX1 is coupled to the row hammer refresh control circuit 510, the row hammer refresh address generation circuit 530 and the normal refresh address generation circuit 540 respectively. The first multiplexer MUX1 is configured to receive the address for the row hammer refresh RHR_ADDR, the address for the normal refresh NR_ADDR and the row hammer refresh signal RHR. The first multiplexer MUX1 is configured to, in response to the row hammer refresh signal RHR being at the first level, output the address for the row hammer refresh RHR_ADDR. The first multiplexer MUX1 is configured to, in response to the row hammer refresh signal RHR being at the second level, output the address for the normal refresh NR_ADDR.

In the example of the present application, referring to FIG. 11, being within the pulse range of the row hammer refresh signal RHR, that is, when the row hammer refresh signal RHR is at a high level (a first level), the first multiplexer MUX1 outputs the address for the row hammer refresh RHR_ADDR to perform the row hammer refresh. Accordingly, being out of the pulse range of the row hammer refresh signal RHR. That is, when the row hammer refresh signal RHR is at a low level (a second level), the first multiplexer MUX1 outputs the address for the normal refresh NR_ADDR to perform a normal refresh.

It may be understood that according to the level of the row hammer refresh signal RHR, the normal refresh and the row hammer refresh are respectively performed, thus, the row hammer problem is effectively solved and the normal refresh in the memory is ensured; therefore, the accuracy of data in the memory cell can be effectively guaranteed.

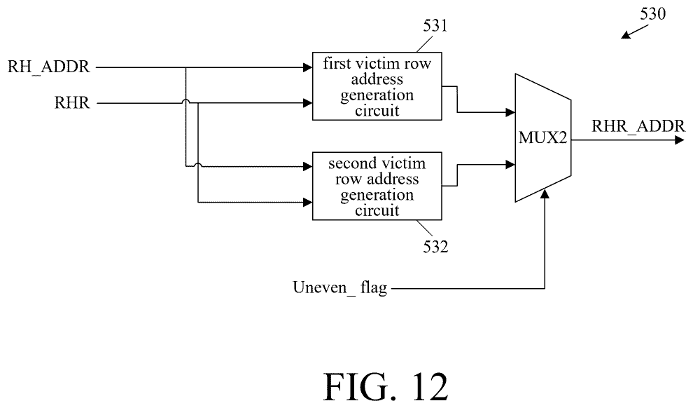

As shown in FIG. 12, in some examples of the present application, the row hammer refresh address generation circuit 530 includes, e.g., a first victim row address generation circuit 531 and a second victim row address generation circuit 532.

In the example of the present application, the first victim row address generation circuit 531 is coupled to the aggressor row address determination circuit 520 and the row hammer refresh control circuit 510. The first victim row address generation circuit 531 is configured to receive the address of the aggressor row RH_ADDR and the row hammer refresh signal RHR, and generate the address of the victim row located on one side of the address of the aggressor row RH_ADDR.

As shown in FIG. 6, in some examples of the present application, the distances between two adjacent word lines are uneven, and the two word lines whose last bits of the row address are inverted are relatively close to each other. Accordingly, the first victim row address generation circuit 531 may invert the lowest bit of the address of the aggressor row to obtain the address of the victim row on the side closer to the address of the aggressor row. For example, the first victim row address generation circuit 531 may invert the lowest bit of the address of the aggressor row 0100 to obtain the address of the victim row 0101 on the side closer to the address of the aggressor row 0100.

In some other examples of the present application, the distances between two adjacent word lines are uneven, and the two word lines whose last bits of the row address are inverted are relatively far from each other. Accordingly, the first victim row address generation circuit 531 may add 1 to the address of the aggressor row, then invert the lowest bit of the address of the aggressor row, and then decrement the address of the aggressor row by 1 to obtain and output the address of the victim row on the side closer to the address of the aggressor row. For example, the first victim row address generation circuit 531 may add 1 to the address of the aggressor row 0100 to obtain 0101, then invert the lowest bit of the 0101 to obtain 0100, then decrement the address of the aggressor row 0100 by 1 to obtain the address of the victim row 0011 on the side closer to the address of the aggressor row 0100.

In the example of the present application, the second victim row address generation circuit 532 is coupled to the aggressor row address determination circuit 520 and the row hammer refresh control circuit 510. The second victim row address generation circuit 532 is configured to receive the address of the aggressor row RH_ADDR and the row hammer refresh signal RHR, and generate the address of the victim row located on both sides of the address of the aggressor row RH_ADDR.

Referring to FIG. 6, the second victim row address generation circuit 532 may set the address of the aggressor row 0100±1 to obtain the addresses of the victim rows 0101 and 0011 located on both sides of the address of the aggressor row 0100; the second victim row address generation circuit 532 may set the address of the aggressor row 0100±2 to obtain the addresses of the victim rows 0110 and 0010 located on both sides of the address of the aggressor row 0100.

Accordingly, the second victim row address generation circuit 532 may also set the address of the aggressor row RH_ADDR±3, ±4, or ±5, which may be set according to requirements, and is not limited here.

In some examples of the present application, as shown in FIG. 12, the row hammer refresh address generation circuit 530 further includes a second multiplexer MUX2. The second multiplexer MUX2 is coupled to the first victim row address generation circuit 531, the second victim row address generation circuit 532 and the row hammer refresh control circuit 510, respectively.

In the example of the present application, the second multiplexer MUX2 is configured to receive the uneven refresh flag signal Uneven_flag, and according to the uneven refresh flag signal Uneven_flag, select one of the output results of the first victim row address generation circuit 531 and the second victim row address generation circuit 532, and output the selected one as the address for the row hammer refresh RHR_ADDR.

Referring to FIG. 11, when the uneven refresh flag signal Uneven_flag is at the first level (e.g., high level), the uneven refresh flag signal Uneven_flag indicates to perform an uneven refresh for the victim row located on one side of the aggressor row. Then, the second multiplexer MUX2 selects the output result of the first victim row address generation circuit 531 for output. That is, the second multiplexer MUX2 outputs the address of the victim row located on one side of the address of the aggressor row RH_ADDR to perform an uneven refresh.

Alternatively, when the uneven refresh flag signal Uneven_flag is at the second level (e.g., low level), the uneven refresh flag signal Uneven_flag indicates to perform a refresh for the victim rows located on both sides of the aggressor row. Then, the second multiplexer MUX2 selects the output result of the second victim row address generation circuit 532 for output. That is, the second multiplexer MUX2 outputs the addresses of the victim rows located on both sides of the address of the aggressor row RH_ADDR to perform an even refresh.

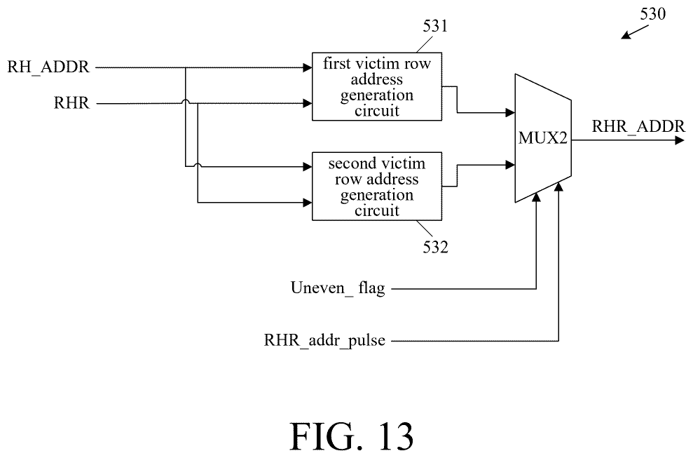

In some examples of the present application, as shown in FIG. 13, the second multiplexer MUX2 is also configured to receive the row hammer refresh address generation signal RHR_addr_pulse, and based on the uneven refresh flag signal Uneven_flag and the row hammer refresh address generation signal RHR_addr_pulse, select to output the address of the victim row located on one side of the address of the aggressor row or the addresses of the victim rows located on both sides of the address of the aggressor row. That is, select one of the output results of the first victim row address generation circuit 531 and the second victim row address generation circuit 532 to be output as the address for the row hammer refresh RHR_ADDR.

It may be understood that the uneven refresh flag signal Uneven_flag and the row hammer refresh address generation signal RHR_addr_pulse are jointly taken as the control signal of the second multiplexer MUX2; thus, the generation of the address for the row hammer refresh RHR_ADDR may be more accurately controlled to avoid errors.

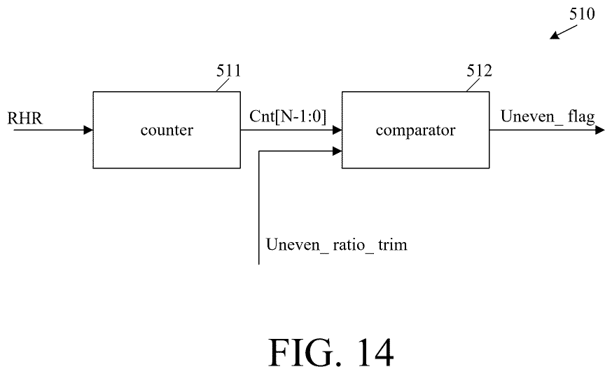

In some examples of the present application, as shown in FIG. 14, the row hammer refresh control circuit 510 includes a counter 511 and a comparator 512. The comparator 512 is coupled to the counter 511. The counter 511 is configured to record the number of pulses of the row hammer refresh signal RHR and output the number of pulses as a count value Cnt[N−1:0], where the number of bits in the count value Cnt[N−1:0] is N. The comparator 512 is configured to compare the count value Cnt[N−1:0] with the adjustment signal Uneven_ratio_trim, and output the corresponding uneven refresh flag signal Uneven_flag according to the result of comparing.

In some examples of the present application, referring to FIG. 14, the comparator 512 is further configured to, when the count value Cnt[N−1:0] matches the adjustment signal Uneven_ratio_trim, output the uneven refresh flag signal Uneven_flag indicating to perform the uneven refresh for the victim row located on one side of the aggressor row; otherwise, the comparator 512 is configured to output the uneven refresh flag signal Uneven_flag indicating to perform a refresh for the victim rows on both sides of the aggressor row.

In the example of the present application, each pulse of the row hammer refresh signal RHR causes the count value Cnt[N−1:0] to increment by 1. Furthermore, the comparator 512 may compare at least some bits of the count value Cnt[N−1:0] incremented each time with the adjustment signal Uneven_ratio_trim, and output the uneven refresh flag signal Uneven_flag of the corresponding level according to the result of comparing. For example, the adjustment signal Uneven_ratio_trim is set to a two-bit binary value 11 (e.g., 2′b11), and if the last two bits Cnt[N−1:0] in the count value Cnt[N−1:0] are equal to 2′b11, then the uneven refresh flag signal Uneven_flag at the first level is output to indicate to perform an uneven refresh for the victim row located on one side of the aggressor row; otherwise, the uneven refresh flag signal Uneven_flag at the second level is output to indicate to perform an uneven refresh for the victim rows located on both sides of the aggressor row.

In some examples, the adjustment signal Uneven_ratio_trim represents the proportion of the uneven refresh in the row hammer refresh, and the proportion of the uneven refresh in row hammer refresh may be adjusted by changing the adjustment signal Uneven_ratio_trim. For example, the adjustment signal Uneven_ratio_trim is set to 2′b11, since there are four two-bit binary numbers, including 2′b00, 2′b01, 2′b10, and 2′b11, and 2′b11 is only one of them. Therefore, at this point, the proportion of the uneven refresh in the row hammer refresh is one quarter.

In some examples, the uneven refresh flag signal Uneven_flag is generated according to the adjustment signal Uneven_ratio_trim, so that a certain proportion of the row hammer refresh is taken as the uneven refresh; thus, the effect of the row hammer refresh is ensured and power consumption is saved. Meanwhile, the proportion of the uneven refresh in row hammer refresh may be adjusted according to needs, thereby improving the flexibility of row hammer refresh.

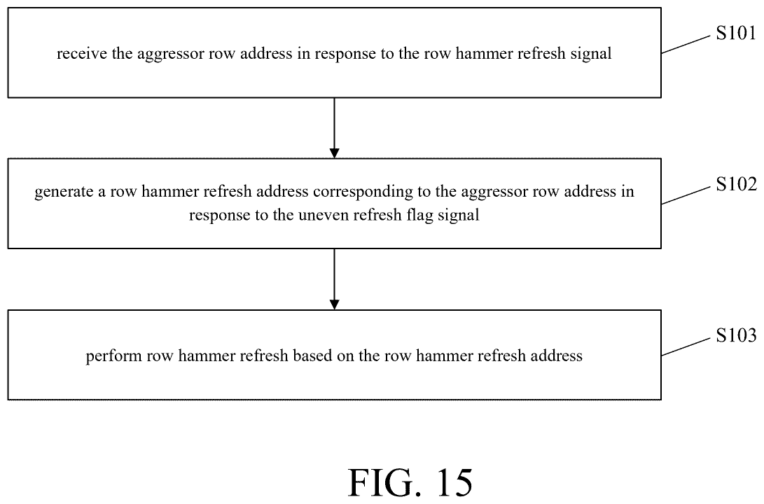

FIG. 15 is a schematic flowchart of the implementation of a hammer refreshing method provided by an example of the present application. The method shown in FIG. 15 may be performed by the peripheral circuit 210 shown in FIG. 1. As shown in FIG. 15, the row hammer refreshing method includes operations S101 to S103, which will be explained in conjunction with each operation.

At S101, in response to the row hammer refresh signal, the address of the aggressor row may be received.

At S102, in response to the uneven refresh flag signal, an address for a row hammer refresh corresponding to the address of the aggressor row may be generated. If the uneven refresh flag signal indicates to perform the uneven refresh for the victim row located on one side of the aggressor row, the address for the row hammer refresh may include the address of the victim row located on one side of the aggressor row.

At S103, a row hammer refresh based on the address for the row hammer refresh may be performed.

Referring to FIG. 11, in some examples of the present application, the peripheral circuit 210 may receive the address of the aggressor row RH_ADDR in case of being triggered by the pulse in the row hammer refresh signal RHR. The peripheral circuit 210 may generate the address for the row hammer refresh RHR_ADDR corresponding to the address of the aggressor row RH_ADDR according to the level of the uneven refresh flag signal Uneven_flag. The peripheral circuit 210 may perform a row hammer refresh based on the address for the row hammer refresh RHR_ADDR.

In some examples of the present application, if the uneven refresh flag signal Uneven_flag is at the first level, the address for the row hammer refresh RHR_ADDR includes the address of the victim row located on one side of the aggressor row side. For example, referring to FIG. 11, when the address of the aggressor row RH_ADDR is C, the uneven refresh flag signal Uneven_flag is at the first level (the example in FIG. 11 is high level); then, the address for the row hammer refresh RHR_ADDR is/C, where the victim row/C is located on one side of the aggressor row C.

In some examples of the present application, if the uneven refresh flag signal Uneven_flag indicates to perform a refresh for the victim rows on both sides of the aggressor row, the address for the row hammer refresh RHR_ADDR includes addresses of victim rows located on both sides of the address of the aggressor row. For example, referring to FIG. 11, when the address of the aggressor row RH_ADDR is A, the uneven refresh flag signal Uneven_flag is at the second level (the example in FIG. 11 is low level); then, the address for the row hammer refresh RHR_ADDR includes A−1 and A+1, where the victim rows A−1 and A+1 are located on both sides of the aggressor row A respectively.

It may be understood that a certain proportion of row hammer refreshes is taken as the uneven refresh, and only the address of the victim row located on one side of the aggressor row is considered as the address for the row hammer refresh RHR_ADDR. Thus, the effect of row hammer refresh is ensured, and power consumption is saved.

An example of the present application further provides a memory system, including: one or more memory devices as provided by examples of the present application, and a memory controller. The memory controller is coupled to the memory device and controls the memory device.

Here, the internal composition of the memory system may be understood with reference to the aforementioned FIG. 1, and some application scenarios of the memory system may be understood with reference to the aforementioned FIGS. 2A and 2B, which will not be repeated here.

An example of the present application also provides a refresh address generation circuit, including: a row hammer refresh control circuit, an aggressor row address determination circuit, and a row hammer refresh address generation circuit. The row hammer refresh control circuit is configured to generate a row hammer refresh signal and an uneven refresh flag signal according to a refresh command signal and an adjustment signal. The aggressor row address determination circuit, coupled to the row hammer refresh control circuit, configured to output an address of the aggressor row in response to the row hammer refresh signal. The row hammer refresh address generation circuit is, coupled to the row hammer refresh control circuit and the aggressor row address determination circuit respectively, and configured to generate an address for a row hammer refresh corresponding to the address of the aggressor row in response to the row hammer refresh signal and the uneven refresh flag signal. If the uneven refresh flag signal indicates to perform the uneven refresh for the victim row located on one side of the aggressor row, the address for the row hammer refresh includes the address of the victim row located on one side of the aggressor row. The adjustment signal represents the proportion of the uneven refresh in the row hammer refresh.

In some examples of the present application, the distances from the word lines located on both sides of the aggressor row to the aggressor row are not equal. The refresh address generation circuit is further configured to: take the word line on the side closer to the aggressor row as the victim row to perform an uneven refresh.

In some examples of the present application, if the uneven refresh flag signal indicates to perform a refresh for the victim rows on both sides of the aggressor row, the address for the row hammer refresh includes addresses of victim rows located on both sides of the address of the aggressor row.

In some examples of the present application, the uneven refresh flag signal being at a high level indicates to perform the uneven refresh for the victim row located on one side of the aggressor row; and the uneven refresh flag signal being at a low level indicates to perform the refresh for the victim rows on both sides of the aggressor row.

In some examples of the present application, the row hammer refresh control circuit is further configured to generate a row hammer refresh address generation signal according to the refresh command signal and the adjustment signal. The row hammer refresh address generation circuit is further configured to generate the address for the row hammer refresh in response to the row hammer refresh address generation signal, the row hammer refresh signal and the uneven refresh flag signal.

In some examples of the present application, the uneven refresh flag signal indicates to perform the uneven refresh for the victim row located on one side of the aggressor row; the row hammer refresh address generation signal includes a single pulse signal corresponding to the row hammer refresh signal. And the uneven refresh flag signal indicates to perform a refresh for the victim rows on both sides of the aggressor row, the row hammer refresh address generation signal includes a double pulse signal corresponding to the row hammer refresh signal.

In some examples of the present application, the refresh address generation circuit further includes: a normal refresh address generation circuit. The normal refresh address generation circuit is coupled to the row hammer refresh control circuit. The normal refresh address generation circuit is configured to receive the refresh command signal and the row hammer refresh signal, and output an address for a normal refresh according to the refresh command signal and the row hammer refresh signal.

In some examples of the present application, the refresh address generation circuit further includes: a first multiplexer. The first multiplexer is coupled to the row hammer refresh control circuit, the row hammer refresh address generation circuit and the normal refresh address generation circuit respectively. The first multiplexer is configured to: receive the address for the row hammer refresh, the address for the normal refresh and the row hammer refresh signal; in response to the row hammer refresh signal being at the first level, output the address for the row hammer refresh; or in response to the row hammer refresh signal being at the second level, output the address for the normal refresh.

In some examples of the present application, the row hammer refresh address generation circuit further includes: a first victim row address generation circuit and a second victim row address generation circuit. The first victim row address generation circuit is coupled to the aggressor row address determination circuit and the row hammer refresh control circuit, and configured to receive the address of the aggressor row and the row hammer refresh signal, and generate the address of the victim row located on one side of the address of the aggressor row. The second victim row address generation circuit is coupled to the aggressor row address determination circuit and the row hammer refresh control circuit, and configured to receive the address of the aggressor row and the row hammer refresh signal, and generate the addresses of the victim rows located on both sides of the address of the aggressor row.

In some examples of the present application, the row hammer refresh address generation circuit further includes: a second multiplexer. The second multiplexer is coupled to the first victim row address generation circuit, the second victim row address generation circuit and the row hammer refresh control circuit respectively. The second multiplexer is configured to, in response to the uneven refresh flag signal indicating to perform the uneven refresh for the victim row located on one side of the aggressor row, output the address of the victim row located on one side of the address of the aggressor row; and in response to the uneven refresh flag signal indicating to perform a refresh for the victim rows on both sides of the aggressor row, output addresses of victim rows located on both sides of the address of the aggressor row.

In some examples of the present application, the row hammer refresh control circuit includes: a counter and a comparator. The counter is configured to record the number of pulses of the row hammer refresh signal and output the number of pulses as a count value. The comparator is coupled to the counter and configured to compare the count value with the adjustment signal, and output the corresponding uneven refresh flag signal according to the result of comparing.

In some examples of the present application, the comparator is further configured to, when the count value matches the adjustment signal, output the uneven refresh flag signal indicating to perform the uneven refresh for the victim row located on one side of the aggressor row, otherwise, output the uneven refresh flag signal indicating to perform a refresh for the victim rows on both sides of the aggressor row.

It should be noted that, in this description, the terms “including”, “containing” or any other variations thereof are intended to cover a non-exclusive inclusion, such that a process, method, article or device that includes a series of elements includes not only those elements but also other elements not expressly listed or that are inherent to the process, method, article or device. Without further limitation, an element defined by the statement “including a . . . ” does not exclude the presence of additional identical elements in a process, method, article, or device that includes that element.

The serial numbers of examples of the present application described above are for the purpose of description only, and do not represent the advantages and disadvantages of the examples. The methods disclosed in several method examples provided in the present application may be combined arbitrarily without conflicts to obtain new method examples. The features disclosed in several product examples provided in the present application may be combined arbitrarily without conflicts to obtain new product examples. The features disclosed in several method or device examples provided in the present application may be combined arbitrarily without conflict to obtain new method examples or device examples.

The above is only specific implementations of the present application, but the claimed scope of the present application is not limited thereto, and changes or substitutions within the technical scope disclosed in the present application that may be easily conceived by those skilled in the art shall fall within the claimed scope of the present application.

What is claimed is:

1. A memory device, comprising:
an array of memory cells including multiple word lines, and memory cells coupled to the word lines; and
a peripheral circuit coupled to the multiple word lines, and configured to:
determine an aggressor row; and
perform an uneven refresh for a victim row located on one side of the aggressor row.

2. The memory device of claim 1, wherein the peripheral circuit includes:
a row hammer refresh control circuit configured to generate a row hammer refresh signal and an uneven refresh flag signal according to a refresh command signal and an adjustment signal;
an aggressor row address determination circuit coupled to the row hammer refresh control circuit, and configured to, in response to the row hammer refresh signal, output an address of an aggressor row; and
a row hammer refresh address generation circuit coupled to the row hammer refresh control circuit and the aggressor row address determination circuit respectively, and configured to, in response to the row hammer refresh signal and the uneven refresh flag signal, generate an address for a row hammer refresh corresponding to the address of the aggressor row;
wherein, if the uneven refresh flag signal indicates to perform the uneven refresh for the victim row located on the one side of the aggressor row, then the address for the row hammer refresh includes an address of the victim row located on the one side of the aggressor row.

3. The memory device of claim 2, wherein the adjustment signal represents a proportion of the uneven refresh in the row hammer refresh.

4. The memory device of claim 2, wherein if the uneven refresh flag signal indicates to perform a refresh for victim rows on both sides of the aggressor row, then the address for the row hammer refresh includes addresses of victim rows located on the both sides of the address of the aggressor row.

5. The memory device of claim 4, wherein,
the uneven refresh flag signal being at a high level indicates to perform the uneven refresh for the victim row located on the one side of the aggressor row; and
the uneven refresh flag signal being at a low level indicates to perform the refresh for the victim rows on the both sides of the aggressor row.

6. The memory device of claim 2, wherein,
the row hammer refresh control circuit is further configured to generate a row hammer refresh address generation signal according to the refresh command signal and the adjustment signal; and
the row hammer refresh address generation circuit is further configured to, in response to the row hammer refresh address generation signal, the row hammer refresh signal, and the uneven refresh flag signal, generate the address for the row hammer refresh.

7. The memory device of claim 6, wherein,
if the uneven refresh flag signal indicates to perform the uneven refresh for the victim row located on the one side of the aggressor row, then the row hammer refresh address generation signal includes a single pulse signal corresponding to the row hammer refresh signal; and
if the uneven refresh flag signal indicates to perform the refresh for victim rows on both sides of the aggressor row, then the row hammer refresh address generation signal includes a double pulse signal corresponding to the row hammer refresh signal.

8. The memory device of claim 2, wherein the peripheral circuit further includes:
a normal refresh address generation circuit coupled to the row hammer refresh control circuit, and configured to:
receive the refresh command signal and the row hammer refresh signal; and
output an address for a normal refresh according to the refresh command signal and the row hammer refresh signal.

9. The memory device of claim 8, wherein the peripheral circuit further includes:
a first multiplexer coupled to the row hammer refresh control circuit, the row hammer refresh address generation circuit, and the normal refresh address generation circuit respectively, and configured to:
receive the address for the row hammer refresh, the address for the normal refresh, and the row hammer refresh signal; and
output the address for the row hammer refresh in response to the row hammer refresh signal being at a first level, or output the address for the normal refresh in response to the row hammer refresh signal being at a second level.

10. The memory device of claim 2, wherein the row hammer refresh address generation circuit includes:
a first victim row address generation circuit coupled to the aggressor row address determination circuit and the row hammer refresh control circuit, and configured to: receive the address of the aggressor row and the row hammer refresh signal, and generate the address of the victim row located on the one side of the address of the aggressor row; and
a second victim row address generation circuit coupled to the aggressor row address determination circuit and the row hammer refresh control circuit, and configured to: receive the address of the aggressor row and the row hammer refresh signal, and generate addresses of victim rows located on both sides of the address of the aggressor row.

11. The memory device of claim 10, wherein the row hammer refresh address generation circuit further includes:
a second multiplexer coupled to the first victim row address generation circuit, the second victim row address generation circuit, and the row hammer refresh control circuit respectively, and configured to:
in response to the uneven refresh flag signal indicating to perform the uneven refresh for the victim row located on the one side of the aggressor row, output the address of the victim row located on the one side of the address of the aggressor row; and
in response to the uneven refresh flag signal indicating to perform a refresh for the victim rows on the both sides of the aggressor row, output the addresses of the victim rows located on the both sides of the address of the aggressor row.

12. The memory device of claim 2, wherein the row hammer refresh control circuit includes:
a counter configured to record a number of pulses of the row hammer refresh signal and output the number of pulses as a count value; and
a comparator coupled to the counter, and configured to:
compare the count value with the adjustment signal; and
output the corresponding uneven refresh flag signal according to a result of comparing.

13. The memory device of claim 12, wherein,
the comparator is further configured to:
when the count value matches the adjustment signal, output the uneven refresh flag signal indicating to perform the uneven refresh for the victim row located on the one side of the aggressor row; and
when the count value does not match the adjustment signal, output the uneven refresh flag signal indicating to perform a refresh for the victim rows on both sides of the aggressor row.

14. The memory device of claim 1, wherein,
distances from word lines located on both sides of the aggressor row to the aggressor row are not equal; and
the peripheral circuit is further configured to take a word line located on one side closer to the aggressor row as the victim row to perform the uneven refresh.

15. The memory device of claim 1, wherein the memory device includes a Dynamic Random Access Memory.

16. A memory system, comprising:
one or more memory devices, each comprising:
an array of memory cells including multiple word lines, and memory cells coupled to the word lines; and
a peripheral circuit coupled to the multiple word lines, and configured to:
determine an aggressor row; and
perform an uneven refresh for a victim row located on one side of the aggressor row; and
a memory controller coupled to the memory devices and configured to control the memory device.

17. The memory system of claim 16, wherein the peripheral circuit includes:
a row hammer refresh control circuit configured to generate a row hammer refresh signal and an uneven refresh flag signal according to a refresh command signal and an adjustment signal;
an aggressor row address determination circuit coupled to the row hammer refresh control circuit, and configured to, in response to the row hammer refresh signal, output an address of an aggressor row; and
a row hammer refresh address generation circuit coupled to the row hammer refresh control circuit and the aggressor row address determination circuit respectively, and configured to, in response to the row hammer refresh signal and the uneven refresh flag signal, generate an address for a row hammer refresh corresponding to the address of the aggressor row;
wherein, if the uneven refresh flag signal indicates to perform the uneven refresh for the victim row located on the one side of the aggressor row, then the address for the row hammer refresh includes an address of the victim row located on the one side of the aggressor row.

18. A refresh address generation circuit, comprising:
a row hammer refresh control circuit configured to generate a row hammer refresh signal and an uneven refresh flag signal according to a refresh command signal and an adjustment signal;
an aggressor row address determination circuit coupled to the row hammer refresh control circuit, and configured to, in response to the row hammer refresh signal, output an address of an aggressor row; and
a row hammer refresh address generation circuit coupled to the row hammer refresh control circuit and the aggressor row address determination circuit respectively, and configured to, in response to the row hammer refresh signal and the uneven refresh flag signal, generate an address for a row hammer refresh corresponding to the address of the aggressor row;
wherein, if the uneven refresh flag signal indicates to perform an uneven refresh for a victim row located on one side of the aggressor row, then the address for the row hammer refresh includes the address of the victim row located on the one side of the aggressor row.

19. The refresh address generation circuit of claim 18, further comprising:
a normal refresh address generation circuit coupled to the row hammer refresh control circuit, and configured to:
receive the refresh command signal and the row hammer refresh signal; and
output an address for a normal refresh according to the refresh command signal and the row hammer refresh signal.

20. The refresh address generation circuit of claim 19, further comprising:
a first multiplexer coupled to the row hammer refresh control circuit, the row hammer refresh address generation circuit and the normal refresh address generation circuit respectively, and configured to:
receive the address for the row hammer refresh, the address for the normal refresh, and the row hammer refresh signal; and
output the address for the row hammer refresh in response to the row hammer refresh signal being at a first level, or output the address for the normal refresh in response to the row hammer refresh signal being at a second level.
